(19) United States
(12) Patent Application Publication
(10) Pub. No.: US 2017/0175292 A1
(43) Pub. Date: Jun. 22, 2017

(54) SAPPHIRE SUBSTRATE

(71) Applicant: Rigidtech Microelectronics Corp., Taoyuan County (TW)

(72) Inventors: Wen-Ching Hung, Taoyuan City (TW); Cheng-Huang Kuo, Tainan City (TW)

(21) Appl. No.: 14/975,853

(22) Filed: Dec. 20, 2015

(51) Int. Cl. C30B 29/20; H01L 33/00; H01L 33/22

(52) U.S. Cl. CPC C30B 29/20; H01L 33/22; H01L 33/007

(57) ABSTRACT

A sapphire substrate including a plurality of tapered structures is provided. The tapered structures are protruded from an upper surface of the sapphire substrate. The crystalline direction of the upper surface is (0001). Each of the tapered structures has three crystalline surfaces of a first group, three crystalline surfaces of a second group, and an axis perpendicular to the upper surface and passing through the apex of the tapered structure. The crystalline surfaces of the first group are rotationally symmetric to the axis by 120 degrees, and the crystalline surfaces of the second group are rotationally symmetric to the axis by 120 degrees. The crystalline direction of one of the crystalline surfaces of the first group is (11̅02). The crystalline direction located in the center of one of the crystalline surfaces of the second group is (112̅3).

### BACKGROUND OF THE INVENTION

Field of the Invention

The invention relates to a substrate, and more particularly, to a sapphire substrate.

Description of Related Art

The light-emitting diode (LED) is a light-emitting element formed by a compound semiconductor. Via the combination of electrons and holes, electrical energy can be converted to and released in the form of light energy. The LED has advantages such as power-saving, small size, short reaction time, and long life, and is therefore currently widely applied in areas of display and illumination. In recent years, to reduce the costs of the LED and to broaden the application of the LED, how to increase the luminous efficiency of the LED is an important current research object. In particular, the internal quantum efficiency (IQE) of LED electroluminescence is in actuality an important factor affecting the overall luminous efficiency of the LED.

In general, the better the semiconductor epitaxial quality of the LED, such as low defect density, the higher the IQE of the LED. To increase the luminous efficiency of the LED, a prior art uses a patterned substrate with different LED semiconductor materials to perform epitaxy. In the case of a gallium nitride (GaN) LED, currently a sapphire substrate having a plurality of microstructures is used to grow a GaN epitaxial thin film to inhibit lateral growth of GaN so as to prevent the generation of defects between lateral-grown GaN and forward-grown GaN. However, the effectiveness of a patterned substrate in inhibiting lateral growth of GaN on the microstructures is limited, such that GaN still grows on the sides of the microstructures. Therefore, the defect density of a GaN epitaxial thin film cannot be readily reduced, and the luminous efficiency of the LED cannot be readily increased.

### SUMMARY OF THE INVENTION

The invention provides a sapphire substrate. The epitaxial structure defect density of a light-emitting diode grown on the sapphire substrate is low, and the luminous efficiency of the light-emitting diode is high.

A sapphire substrate of the invention includes a plurality of tapered structures. The tapered structures are protruded from an upper surface of the sapphire substrate. The crystalline direction of the upper surface is (0001). Each of the tapered structures has three crystalline surfaces of a first group, three crystalline surfaces of a second group, and an axis perpendicular to the upper surface and passing through the apex of the tapered structure. The crystalline surfaces of the first group and the crystalline surfaces of the second group are alternately arranged to surround the axis. The crystalline surfaces of the first group are rotationally symmetric to the axis by 120 degrees, and the crystalline surfaces of the second group are rotationally symmetric to the axis by 120 degrees. The crystalline direction of one of the crystalline surfaces of the first group is (11̅02). The crystalline direction located in the center of one of the crystalline surfaces of the second group is (112̅3).

In an embodiment of the invention, the crystalline surfaces of the first group are planar, and the crystalline surfaces of the second group are curved.

In an embodiment of the invention, each of the crystalline surfaces of the second group is disposed between two adjacent crystalline surfaces of the first group. The crystalline surfaces of the first group and the crystalline surfaces of the second group are connected to one another.

In an embodiment of the invention, the ratio of the total area of the crystalline surfaces of the first group and the total area of the crystalline surfaces of the second group is within the range of 0.5 to 9.5.

In an embodiment of the invention, the ratio of the projected area of the tapered structures on the upper surface and the area of the upper surface is within the range of 0.5 to 0.95.

In an embodiment of the invention, the height value of each of the tapered structures is within the range of 1.0 micrometer to 3.5 micrometers.

In an embodiment of the invention, the tapered structures are arranged into a plurality of rows, and the tapered structures of the even-numbered rows are respectively staggered with the tapered structures of the odd-numbered rows.

In an embodiment of the invention, the pitch of two adjacent tapered structures is within the range of 0.5 micrometers to 5.0 micrometers.

Based on the above, the tapered structures are protruded from the upper surface of the sapphire substrate in an embodiment of the invention. The crystalline direction of the upper surface is (0001). Each of the tapered structures has three crystalline surfaces of a first group, three crystalline surfaces of a second group, and an axis perpendicular to the upper surface and passing through the apex of the tapered structure. The crystalline surfaces of the first group and the crystalline surfaces of the second group are alternately arranged to surround the axis. The crystalline surfaces of the first group are rotationally symmetric to the axis by 120 degrees, and the crystalline surfaces of the second group are rotationally symmetric to the axis by 120 degrees. The crystalline direction of one of the crystalline surfaces of the first group is (11̅02). The crystalline direction located in the center of one of the crystalline surfaces of the second group is (112̅3). Therefore, the epitaxial structure defect density of a light-emitting diode grown on the sapphire substrate is low, and the luminous efficiency of the light-emitting diode is high.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A shows a three-dimensional schematic view of a sapphire substrate of an embodiment of the invention.

FIG. 1B shows a schematic top view of a sapphire substrate region A of the embodiment of FIG. 1A.

FIG. 1C shows a schematic cross-sectional view of the sapphire substrate of the embodiment of FIG. 1B along line I-I′.

FIG. 2A to FIG. 2C show a schematic view of the manufacturing method of a sapphire substrate of another embodiment of the invention.

FIG. 3A is a schematic cross-sectional view of a sapphire substrate 200′ of the embodiment of FIG. 2B viewed from a scanning electron microscope.

FIG. 3B is a schematic top view of the sapphire substrate 200′ of the embodiment of FIG. 2B viewed from a scanning electron microscope.

FIG. 4 is a schematic top view of epitaxial gallium nitride on a sapphire substrate of yet another embodiment of the invention viewed from a scanning electron microscope.

### DESCRIPTION OF THE EMBODIMENTS

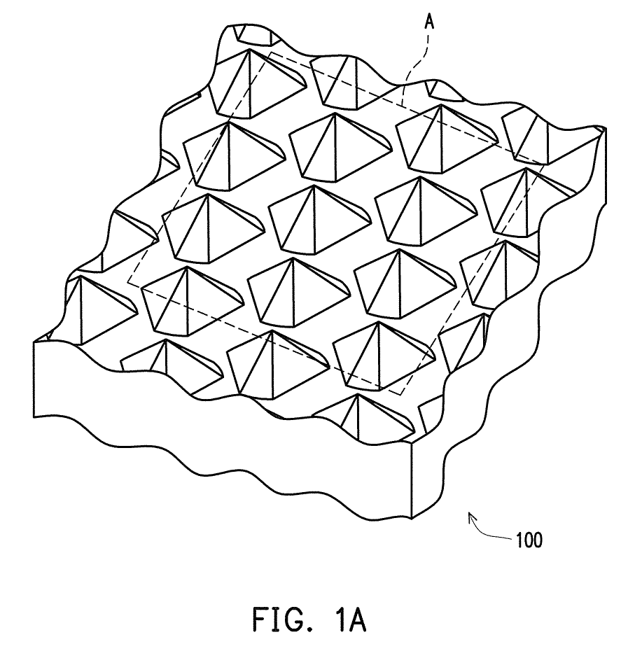

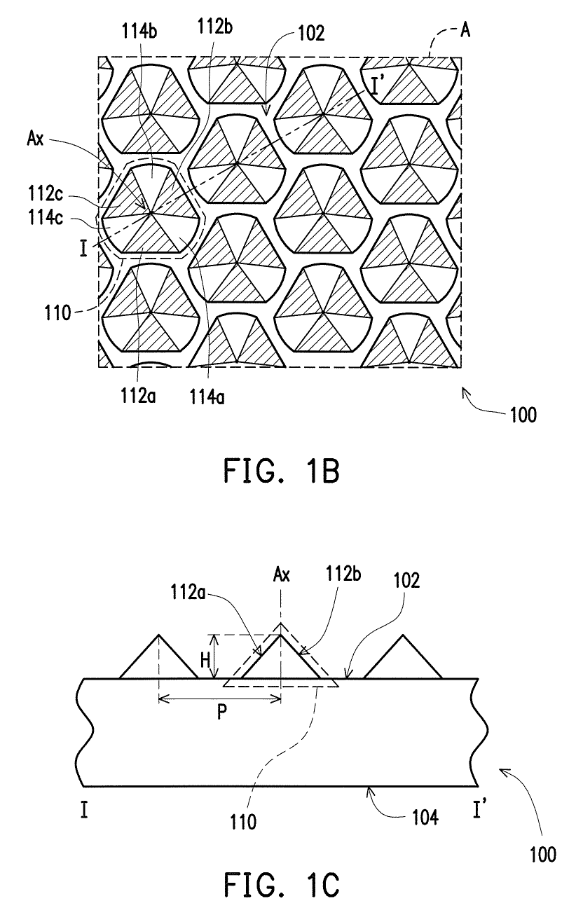

FIG. 1A shows a three-dimensional schematic view of a sapphire substrate of an embodiment of the invention. Specifically, to clearly express each of the components of the sapphire substrate, a sapphire substrate 100 shown in FIG. 1A is only one of the portions of a complete sapphire substrate. In the present embodiment, relevant descriptions of the sapphire substrate 100 represent relevant descriptions of the overall sapphire substrate.

FIG. 1B shows a schematic top view of a sapphire substrate region A of the embodiment of FIG. 1A. Please refer to FIG. 1A and FIG. 1B. In the present embodiment, the sapphire substrate 100 has an upper surface 102 and a lower surface 104 opposite to each other, and the crystalline direction of the upper surface 102 is (0001). Specifically, the sapphire substrate 100 includes a plurality of tapered structures 110, and the tapered structures 110 are protruded from the upper surface 102 of the sapphire substrate 100. The sapphire substrate 100 can be, for instance, a C-plane sapphire substrate 100.

In the present embodiment, each of the tapered structures 110 of the sapphire substrate 100 has three crystalline surfaces of a first group, that is, a crystalline surface 112a, a crystalline surface 112b, and a crystalline surface 112c. Moreover, each of the tapered structures 110 further has three crystalline surfaces of a second group, that is, a crystalline surface 114a, a crystalline surface 114b, and a crystalline surface 114c. Moreover, each of the tapered structures 110 has an axis Ax perpendicular to the upper surface 102 and passing through the apex of the tapered structure 110. Specifically, the lattice arrangement of the sapphire substrate 100 is hexagonal close-packed (HCP). In each of the tapered structures 110 of the sapphire substrate 100, the crystalline surfaces of the first group are alternately arranged with the crystalline surfaces of the second group to surround the axis Ax. Specifically, the crystalline surface 112a, the crystalline surface 112b, and the crystalline surface 112c of the first group and the crystalline surface 114a, the crystalline surface 114b, and the crystalline surface 114c of the second group are alternately arranged to surround the axis Ax. The crystalline surface 112a, the crystalline surface 112b, and the crystalline surface 112c of the first group are rotationally symmetric to the axis Ax by 120 degrees, and the crystalline surface 114a, the crystalline surface 114b, and the crystalline surface 114c of the second group are rotationally symmetric to the axis Ax by 120 degrees.

In the present embodiment, each of the crystalline surfaces of the second group is disposed between two adjacent crystalline surfaces of the first group, and the crystalline surfaces of the first group and the crystalline surfaces of the second group are connected to one another. Specifically, the crystalline surface 114a of the second group is disposed between the adjacent crystalline surface 112a and crystalline surface 112b of the first group, the crystalline surface 114b of the second group is disposed between the adjacent crystalline surface 112b and crystalline surface 112c of the first group, and the crystalline surface 114c of the second group is disposed between the adjacent crystalline surface 112a and crystalline surface 112c of the first group. Moreover, the crystalline surface 112a, the crystalline surface 112b, and the crystalline surface 112c of the first group and the crystalline surface 114a, the crystalline surface 114b, and the crystalline surface 114c of the first group are connected to one another.

In the present embodiment, the tapered structures 110 are arranged into a plurality of rows, and the tapered structures 110 of the even-numbered rows are respectively staggered with the tapered structures 110 of the odd-numbered rows. Specifically, the tapered structures 110 are arranged in a staggered manner, and the tapered structures 110 are evenly arranged on the upper surface 102 of the sapphire substrate 100. Moreover, the ratio of the projected area of the tapered structures 110 on the upper surface 102 and the area of the upper surface 102 is within the range of 0.5 to 0.95, preferably within the range of 0.73 to 0.88. In some embodiments, the tapered structures 110 can also be arranged in a lattice or radially arranged on the upper surface 102, or randomly arranged to form a pattern, and the invention is not limited thereto. Moreover, in other embodiments, the tapered structures 110 can also be disposed on the lower surface 104 of the sapphire substrate 100, or the tapered structures 110 can be disposed on the upper surface 102 and the lower surface 104 of the sapphire substrate 100 at the same time, and the invention is also not limited thereto.

In the present embodiment, the crystalline surfaces of the first group are planar, and the crystalline surfaces of the second group are curved. Specifically, the crystalline surface 112a, the crystalline surface 112b, and the crystalline surface 112c of the first group are substantially flat surfaces, and the crystalline surface 114a, the crystalline surface 114b, and the crystalline surface 114c of the second group are curved, such as a portion of a conic surface. However, in some embodiments, the crystalline surface 112a, the crystalline surface 112b, and the crystalline surface 112c of the first group can also be non-planar, such as curved surfaces, and the crystalline surface 114a, the crystalline surface 114b, and the crystalline surface 114c of the second group can also be planar, and the invention is not limited thereto.

In the present embodiment, each of the crystalline surfaces of the first group has a specific crystalline direction, and each of the crystalline surfaces of the second group also has a specific crystalline direction at the center thereof. The center of each of the crystalline surfaces of the second group refers to, for instance, the position of geometric center of each of the crystalline surfaces of the second group. In the present embodiment, one of the crystalline directions of the crystalline surfaces of the first group is (11̅02), and one of the crystalline directions located in the center of the crystalline surfaces of the second group is (112̅3). Specifically, one of the crystalline directions of the crystalline surface 112a, the crystalline surface 112b, and the crystalline surface 112c of the first group is (11̅02), wherein the crystalline direction of the crystalline surface 112a is, for instance, (11̅02). One of the crystalline directions located in the center of the crystalline surface 114a, the crystalline surface 114b, and the crystalline surface 114c of the second group is (112̅3), wherein the crystalline direction of the crystalline surface 114a is, for instance, (112̅3). In some embodiments, the crystalline surfaces of the tapered structures 110 can also be designed to have other crystalline directions based on actual demand, and the invention is not limited thereto.

Referring further to FIG. 1B, in the present embodiment, the ratio of the total area of the crystalline surface 112a, the crystalline surface 112b, and the crystalline surface 112c of the first group and the total area of the crystalline surface 114a, the crystalline surface 114b, and the crystalline surface 114c of the second group is within the range of 0.5 to 9.5, preferably within the range of 3 to 8. In other embodiments, the crystalline surfaces of the first group and the crystalline surfaces of the second group can also be designed to have other ratios based on actual demand, and the invention is not limited thereto.

FIG. 1C shows a schematic cross-sectional view of the sapphire substrate of the embodiment of FIG. 1B along line I-I′. Please refer to FIG. 1B and FIG. 1C. In the present embodiment, line I-I′ is used as the section line to assist in describing the shapes of the components of the sapphire substrate 100. Line I-I′ of the present embodiment is not intended to limit the invention. In the present embodiment, the height value of each of the tapered structures 110 of the sapphire substrate 100 is within the range of 1.0 micrometer to 3.5 micrometers, preferably within the range of 1.65 micrometers to 1.95 micrometers. Moreover, the pitch of two adjacent tapered structures 110 is within the range of 0.5 micrometers to 5.0 micrometers. In other embodiments, each of the tapered structures 110 of the sapphire substrate 100 can also be designed to have other height values and two adjacent tapered structures 110 of the sapphire substrate 100 can be designed to have other pitch values based on actual demand, and the invention is not limited thereto.

In the present embodiment, when the sapphire substrate 100 is applied in the manufacture of a light-emitting diode, such as applied in the manufacture of a gallium nitride (GaN) light-emitting diode, the sapphire substrate 100 is used as the substrate of light-emitting diode epitaxy, and GaN epitaxy is on the upper surface 102 of the sapphire substrate 100. Specifically, the tapered structures 110 are protruded from the upper surface 102 of the sapphire substrate 100, and the crystalline direction of the upper surface 102 is (0001). In addition to having the crystalline surface 112a, the crystalline surface 112b, and the crystalline surface 112c of the first group, each of the tapered structures 110 further has the crystalline surface 114a, the crystalline surface 114b, and the crystalline surface 114c of the second group. One of the crystalline directions of the crystalline surfaces of the first group is (11̅02), and one of the crystalline directions located in the center of the crystalline surfaces of the second group is (112̅3). In general, in the epitaxy process of GaN, GaN has faster growth rate in the direction of (0001). In the GaN epitaxy process, the crystalline surfaces of each of the tapered structures 110 of the sapphire substrate 100 can inhibit the lateral growth of GaN, such that the growth of GaN in the (0001) direction leads the overall growth of GaN on the sapphire substrate 100. As a result, a flat GaN epitaxy layer is formed. Since the crystalline surfaces inhibit the lateral growth of GaN, the generation of defects between laterally-grown GaN and forward-grown GaN (i.e., growth of GaN on (0001)) can be reduced. In other words, when the sapphire substrate 100 is applied in the manufacture of a light-emitting diode, such as applied in the manufacture of a GaN light-emitting diode, the defect density of the light-emitting diode epitaxial structure is low, such that the internal quantum efficiency of the light-emitting diode is high, and as a result the luminous efficiency of the light-emitting diode is high.

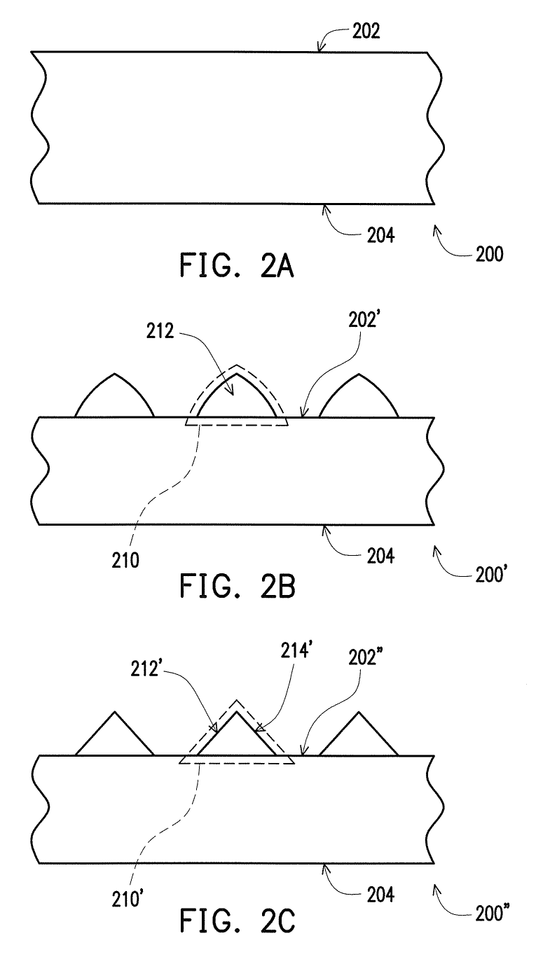

FIG. 2A to FIG. 2C show a schematic view of the manufacturing method of a sapphire substrate of another embodiment of the invention. Please refer first to FIG. 2A. In the present embodiment, first, a sapphire substrate 200 is prepared. The sapphire substrate 200 has an upper surface 202 and a lower surface 204 opposite to each other, and the crystalline direction of the upper surface 202 is (0001). Next, referring to FIG. 2B, etching is performed on the upper surface 202 of the sapphire substrate 200. In the present embodiment, the method of performing etching on the upper surface 202 of the sapphire substrate 200 includes performing a photoresist process on the sapphire substrate 200 to define the positions of the tapered structures 210. Then, dry etching is performed on the upper surface 202 of the sapphire substrate 200, wherein the reaction gases include boron trichloride and chlorine gas, and the etching time is, for instance, within the range of 5 minutes to 60 minutes. Specifically, after etching is performed on the upper surface 202 of the sapphire substrate 200, an etched upper surface 202′ is formed, and a plurality of tapered structures 210 are protruded from the upper surface 202′ of an etched sapphire substrate 200′. Each of the tapered structures 210 has a side surface 212, and the side surfaces 212 are, for instance, conic surfaces.

Next, referring to FIG. 2C, wet etching is performed on the sapphire substrate 200′. In the present embodiment, the method of performing wet etching on the sapphire substrate 200′ includes etching the side surfaces 212 of the tapered structures 210 via an etching solution, such that a plurality of tapered structures 210′ is formed on an upper surface 202″ of an etched sapphire substrate 200″. Specifically, the tapered structures 210′ are similar to the tapered structures 110 of FIG. 1A to FIG. 1C, and the structure of the tapered structures 210′ and relevant descriptions are as provided for the tapered structures 110 of the embodiment of FIG. 1A to FIG. 1C and are not repeated herein. Similarly, the tapered structures 210′ have three crystalline surfaces of a first group, such as a crystalline surface 212′, and the tapered structures 210′ also have three crystalline surfaces of a second group, such as a crystalline surface 214′. In the present embodiment, the crystalline surface 212′ can be, for instance, the crystalline surface 112a of the embodiment of FIG. 1B, and the crystalline surface 214′ can be, for instance, the crystalline surface 114b of the embodiment of FIG. 1B. Alternatively, the crystalline surface 212′ can be, for instance, the crystalline surface 112b of the embodiment of FIG. 1B, and the crystalline surface 214′ can be, for instance, the crystalline surface 114c of the embodiment of FIG. 1B. Moreover, the crystalline surface 212′ can be, for instance, the crystalline surface 112c of the embodiment of FIG. 1B, and the crystalline surface 214′ can be, for instance, the crystalline surface 114a of the embodiment of FIG. 1B.

In the present embodiment, the etching solution is a mixture of sulfuric acid and phosphoric acid. In the mixture, the ratio of sulfuric acid and phosphoric acid is within the range of 1.0:1.0 to 4.0:1.0, and preferably, the ratio of sulfuric acid and phosphoric acid is 1.55:1. Moreover, the etching time is, for instance, 10 seconds to 1800 seconds, and preferably, the etching time for etching the side surfaces 212 of the tapered structures 210 via an etching solution is 180 seconds. Moreover, the etching temperature is, for instance, within the range of 30° C. to 310° C., and preferably, the side surfaces 212 of the tapered structures 210 are etched via an etching solution in an environment of an etching temperature of 235° C. Specifically, in the etching process, the etching solution etches the three crystalline surfaces of the first group of the tapered structures 210′, and the unetched portion between two adjacent crystalline surfaces forms a crystalline surface of the second group of the tapered structures 210′. Specifically, the manufacturing method of a sapphire substrate of the present embodiment can at least be applied to the sapphire substrate 100 of the embodiment of FIG. 1A to FIG. 1C.

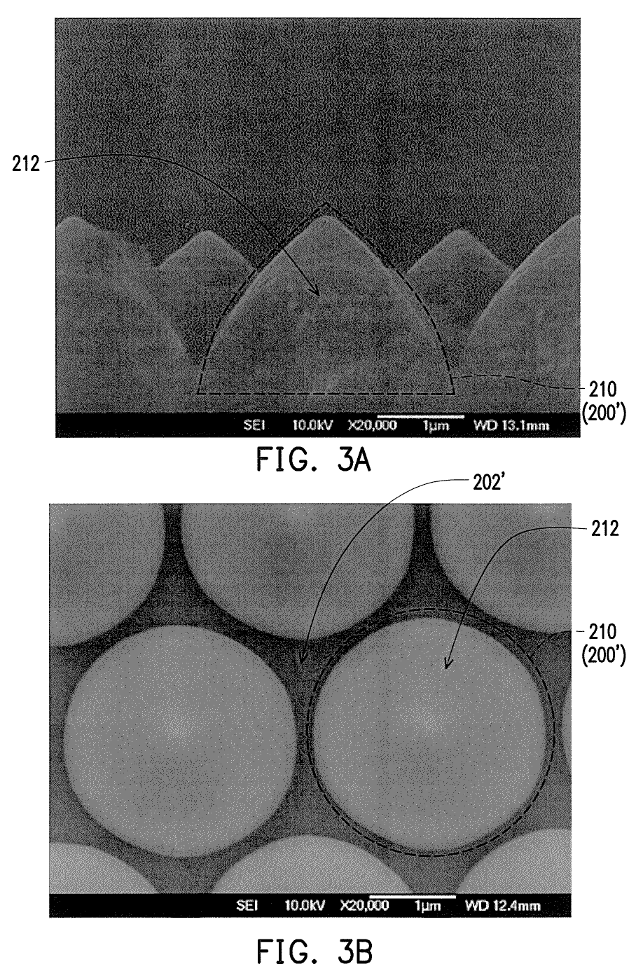

FIG. 3A is a schematic cross-sectional view of the sapphire substrate 200′ of the embodiment of FIG. 2B viewed from a scanning electron microscope, and FIG. 3B is a schematic top view of the sapphire substrate 200′ of the embodiment of FIG. 2B viewed from a scanning electron microscope. Please refer to FIG. 3A and FIG. 3B. In the present embodiment, the tapered structures 210 on the sapphire substrate 200′ have side surfaces 212, and the side surfaces 212 are, for instance, conic surfaces.

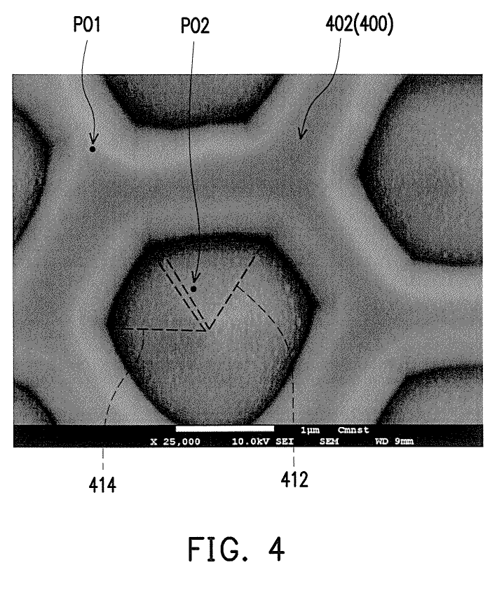

FIG. 4 is a schematic top view of epitaxial gallium nitride on a sapphire substrate of yet another embodiment of the invention viewed from a scanning electron microscope. Please refer to FIG. 4. In the present embodiment, a sapphire substrate 400 is similar to the sapphire substrate 100 of the embodiment of FIG. 1A to FIG. 1C. The structure of the sapphire substrate 400 and relevant descriptions are as provided for the sapphire substrate 100 of the embodiment of FIG. 1A to FIG. 1C and are not repeated herein. In the present embodiment, the sapphire substrate 400 includes a plurality of tapered structures, and the tapered structures are protruded from the upper surface 402 of the sapphire substrate 400. Each of the tapered structures has three crystalline surfaces of a first group, such as a crystalline surface 412, and each of the tapered structures also has three crystalline surfaces of a second group, such as a crystalline surface 414. In the present embodiment, the crystalline surfaces of the first group of each of the tapered structures are similar to the crystalline surfaces of the first group of each of the tapered structures 110 of the embodiment of FIG. 1A to FIG. 1C. Moreover, in the present embodiment, the crystalline surfaces of the second group of each of the tapered structures are similar to the crystalline surfaces of the second group of each of the tapered structures 110 of the embodiment of FIG. 1A to FIG. 1C. Specifically, the GaN epitaxy is on the upper surface 402 of the sapphire substrate 400, and GaN has not yet formed a flat GaN surface.

In the following, (Table 1) lists the results of energy dispersive X-ray spectrometer (EDS) performed on the upper surface 402 of the sapphire substrate 400 after GaN epitaxy on the upper surface 402 of the sapphire substrate 400 of the embodiment of FIG. 4, the position of the elemental analysis is a position PO1 in FIG. 4, and the position PO1 is located at the position between two adjacent tapered structures. Moreover, (Table 2) also lists the results of elemental analysis performed on the upper surface 402 of the sapphire substrate 400 after GaN epitaxy on the upper surface 402 of the sapphire substrate 400 of the embodiment of FIG. 4, the position of the elemental analysis is a position PO2 in FIG. 4, and the position PO2 is located on the surface of the tapered structures, and located at the position of the crystalline surface 412 of the first group. It should be mentioned that, the data listed in the following Table 1 and Table 2 is only the data of one embodiment of the invention, and is not intended to limit the invention. Any person having ordinary skill in the art can make suitable modification to the parameters or the settings of the invention by applying the principles of the invention after reviewing the invention without departing from the scope or spirit of the invention.

TABLE 1

| | Carbon | Nitrogen | Oxygen | Gallium | Aluminum |
|---|---|---|---|---|---|
| Element | (C) | (N) | (O) | (Ga) | (Al) |
| Weight percentage | 5.69 | 9.12 | 0.63 | 80.84 | 1.02 |
| (wt %) | | | | | |
| Atomic percentage | 26.73 | 29.54 | 2.24 | 65.48 | 2.13 |
| (at %) | | | | | |

TABLE 2

| | Carbon | Nitrogen | Oxygen | Gallium | Aluminum |
|---|---|---|---|---|---|
| Element | (C) | (N) | (O) | (Ga) | (Al) |
| Weight percentage | 3.83 | 9.14 | 28.74 | 9.25 | 49.04 |
| (wt %) | | | | | |
| Atomic percentage | 7.76 | 1.14 | 43.68 | 3.23 | 44.19 |
| (at %) | | | | | |

It can be seen from (Table 1) and (Table 2) that, in the present embodiment, the sapphire substrate 400 is located at a position between two adjacent tapered structures (i.e., the position PO1), and the nitrogen content and the gallium content thereof are respectively significantly greater than the nitrogen content and the gallium content of the sapphire substrate 400 located at a position of the crystalline surface 412 of the first group (i.e., the position PO2). Moreover, the oxygen content and the aluminum content of the position PO2 are respectively significantly greater than the oxygen content and the aluminum content of the position PO1. Specifically, since the nitrogen element and the gallium element are the main components of GaN, and the oxygen element and the aluminum element are the main components of the sapphire substrate, the epitaxy situation of GaN at different positions on the sapphire substrate 400 can be known via the above elemental analysis. In the present embodiment, the GaN growth rate of the sapphire substrate 400 at the position between two adjacent tapered structures is significantly higher than that at the position of the crystalline surface 412 of the first group of the sapphire substrate 400. In other words, the tapered structures of the sapphire substrate 400 can inhibit the lateral growth of GaN, such that the growth of GaN in the (0001) direction leads the overall growth of GaN on the sapphire substrate 400. Specifically, as GaN epitaxy occurs, GaN grows along the direction of (0001) at the position between two adjacent tapered structures on the sapphire substrate 400, and gradually covers the tapered structures to form a flat GaN epitaxial layer. In the present embodiment, the sapphire substrate 400 has a similar effect to the sapphire substrate 100 of the embodiment of FIG. 1A to FIG. 1C. When the sapphire substrate 400 is applied in the manufacture of a GaN light-emitting diode, the defect density of the light-emitting diode epitaxial structure is low, and the luminous efficiency of the light-emitting diode is high.

Based on the above, the sapphire substrate of an embodiment of the invention has a plurality of tapered structures, and the tapered structures are protruded from the upper surface of the sapphire substrate. The crystalline direction of the upper surface is (0001). Each of the tapered structures has three crystalline surfaces of a first group, three crystalline surfaces of a second group, and an axis perpendicular to the upper surface and passing through the apex of the tapered structure. The crystalline surfaces of the first group and the crystalline surfaces of the second group are alternately arranged to surround the axis. The crystalline surfaces of the first group are rotationally symmetric to the axis by 120 degrees, and the crystalline surfaces of the second group are rotationally symmetric to the axis by 120 degrees. One of the crystalline directions of the crystalline surfaces of the first group is (11̅02), and one of the crystalline directions located in the center of the crystalline surfaces of the second group is (112̅3). Therefore, the epitaxial structure defect density of a light-emitting diode grown on the sapphire substrate is low, and the luminous efficiency of the light-emitting diode is high.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A sapphire substrate, comprising a plurality of tapered structures, wherein the tapered structures are protruded from an upper surface of the sapphire substrate, a crystalline direction of the upper surface is (0001), each of the tapered structures has three crystalline surfaces of a first group, three crystalline surfaces of a second group, and an axis perpendicular to the upper surface and passing through an apex of the tapered structure, the crystalline surfaces of the first group and the crystalline surfaces of the second group are alternately arranged to surround the axis, wherein the crystalline surfaces of the first group are rotationally symmetric to the axis by 120 degrees, the crystalline surfaces of the second group are rotationally symmetric to the axis by 120 degrees, one of crystalline directions of the crystalline surfaces of the first group is (11̅02), and one of crystalline directions located in a center of the crystalline surfaces of the second group is (112̅3).

2. The sapphire substrate of claim 1, wherein the crystalline surfaces of the first groups are planar, and the crystalline surfaces of the second groups are curved.

3. The sapphire substrate of claim 1, wherein each of the crystalline surfaces of the second group is disposed between two adjacent crystalline surfaces of the first group, and the crystalline surfaces of the first group and the crystalline surfaces of the second group are connected to one another.

4. The sapphire substrate of claim 1, wherein a ratio of a total area of the crystalline surfaces of the first group and a total area of the crystalline surfaces of the second group is within a range of 0.5 to 9.5.

5. The sapphire substrate of claim 1, wherein a ratio of a projected area of the tapered structures on the upper surface and an area of the upper surface is within a range of 0.5 to 0.95.

6. The sapphire substrate of claim 1, wherein a height value of each of the tapered structures is within a range of 1.0 micrometer to 3.5 micrometers.

7. The sapphire substrate of claim 1, wherein the tapered structures are arranged into a plurality of rows, and the tapered structures of even-numbered rows are respectively staggered with the tapered structures of odd-numbered rows.

8. The sapphire substrate of claim 1, wherein a pitch of two adjacent tapered structures is within a range of 0.5 micrometers to 5.0 micrometers.
